(19) United States
(12) Patent Application Publication
(10) Pub. No.: US 2005/0276123 A1
(43) Pub. Date: Dec. 15, 2005

(54) Addressing type serial/parallel data transmitting system

(75) Inventor: Di Tang, Taipei City (TW)

Correspondence Address: BACON & THOMAS, PLLC, 625 SLATERS LANE, FOURTH FLOOR, ALEXANDRIA, VA, 22314, US

(73) Assignee: Tatung Co., Ltd., Taipei City (TW)

(21) Appl. No.: 11/142,266

(22) Filed: Jun. 2, 2005

(30) Foreign Application Priority Data
Jun. 15, 2004 (TW) 093117165

(51) Int. Cl. G11C 5/00

(52) U.S. Cl. 365/189.04

(57) ABSTRACT

An addressing type serial/parallel data transmitting system includes a bus, a data acquisition controller, an addressing type input register, a control end, a microprocessor, and an addressing type output register. The data acquisition controller is electrically connected to the bus for receiving address and data from the bus. The addressing type input register is provided for saving inputting data. The control end controls the input/output states of the addressing type serial/parallel data transmitting system. The microprocessor processes data transmitted from the data acquisition controller. The microprocessor further has a serial/parallel determining circuit for determining whether to output data in serial or in parallel. The addressing type output register is provided for saving desired outputting data processed by the microprocessor.

### BACKGROUND OF THE INVENTION

1. Field of the Invention

The present invention relates to a serial/parallel data transmitting system; and more particularly to an addressing type serial/parallel data transmitting system.

2. Description of Related Art

Conventionally, a computer system comprises electronic components with various functions, and the electronic components are connected by bus to achieve the purpose of inter-communication. In the prior art of I/O Bus, the method of outputting signals in parallel for transmitting data is employed to satisfy the requirement of increasing frequency of the processor core in the current computer system. Moreover, prior method of serial/parallel data transmitting circuit system employs additional RAM (Random Access Memory) for the circuit design, causing higher expense of circuit purchasing and lower integration of the circuit. Also the microprocessor has to access the control with extra work, causing slower speed in operation. Therefore, it is desirable to provide an improved system to mitigate and/or obviate the aforementioned problems.

### SUMMARY OF THE INVENTION

The present invention has been accomplished under the circumstances in view. It is therefore the main object of the present invention to provide a serial/parallel data transmitting system, which uses addressing type data transmission to control data transmission for utilizing memory more efficiently and reducing the cost by purchasing less memory to achieve the same performance.

It is another object of the present invention to provide a serial/parallel data transmitting system, which takes advantages of addressing to control inputs and outputs of the data in order to enhance the integration of the circuit.

The present invention discloses an addressing type serial/parallel data transmitting system, which comprises: a bus; a data acquisition controller electrically connected to the bus, for receiving address and data from the bus; an addressing type input register for saving inputting data; a control end for controlling the input/output states of the addressing type serial/parallel data transmitting system; a microprocessor for processing data transmitted from the data acquisition controller, wherein the microprocessor further comprises a serial/parallel determining circuit for determining whether to output data in serial or in parallel; and an addressing type output register for saving desired outputting data processed by the microprocessor.

The control end is comprised of ALE pins, NWR pins and NRD pins, which collocate with data transmitted by the bus to control the input and output of data.

The present invention also discloses a data transmitting method for an addressing type serial/parallel data transmitting system, which comprises the steps of: (A) determining whether a data is inputted; (B) inputting the data to the addressing type input register in accordance with corresponding address of inputted data; (C) determining whether to transmit the inputted data in serial or in parallel and transmitting the data to the microprocessor; (D) saving the data processed by the microprocessor to the addressing type output register; and (E) outputting the addressing type data in accordance with corresponding address of desired output data; wherein the corresponding addresses in addressing type input and output registers are different.

### BRIEF DESCRIPTION OF THE DRAWINGS

FIG. 1 is the operating environment diagram of one preferred embodiment of the present invention.

FIG. 2 is the functional block diagram of one preferred embodiment of the present invention.

FIG. 3 is the flow chart of one preferred embodiment of the present invention.

### DETAILED DESCRIPTION OF THE PREFERRED EMBODIMENT

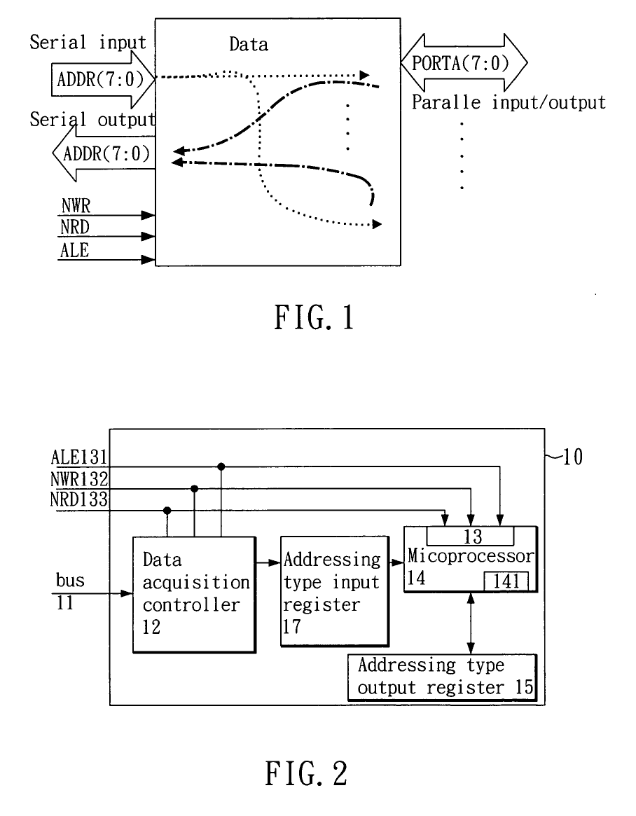

FIG. 1 is the operating environment diagram of the preferred embodiment. Please also refer to FIG. 2, which is the functional block diagram of the preferred embodiment. The addressing type serial/parallel data transmitting system 10 of this preferred embodiment comprises: a bus 11; a data acquisition controller 12; an addressing type input register 17; a control end 13; a microprocessor 14 and an addressing type output register 15. The data acquisition controller 12 is connected to the bus 11 to collects addresses and data inputted by bus 11. The transmission of data is inputted/outputted by the bus 11; and the status of transmission is controlled by the ALE pin 131, NWR pin 132, and NRD pin 133 of the control end 13. The microprocessor 14 comprises a serial/parallel determining circuit 141 for determining either to transmit the desired output data in serial or parallel.

In the preferred embodiment, the bus 11 is an 8-bit transmitting bus. Data inputted/outputted by the bus 11 is in a package format that includes the addresses and data. The address of the package is used to compare with the ALE pin 131, the NRD pin 132, and the NWR pin 133 for determining whether the address of the package is equivalent to the address of the pins, and if true, it begins to perform data transmission.

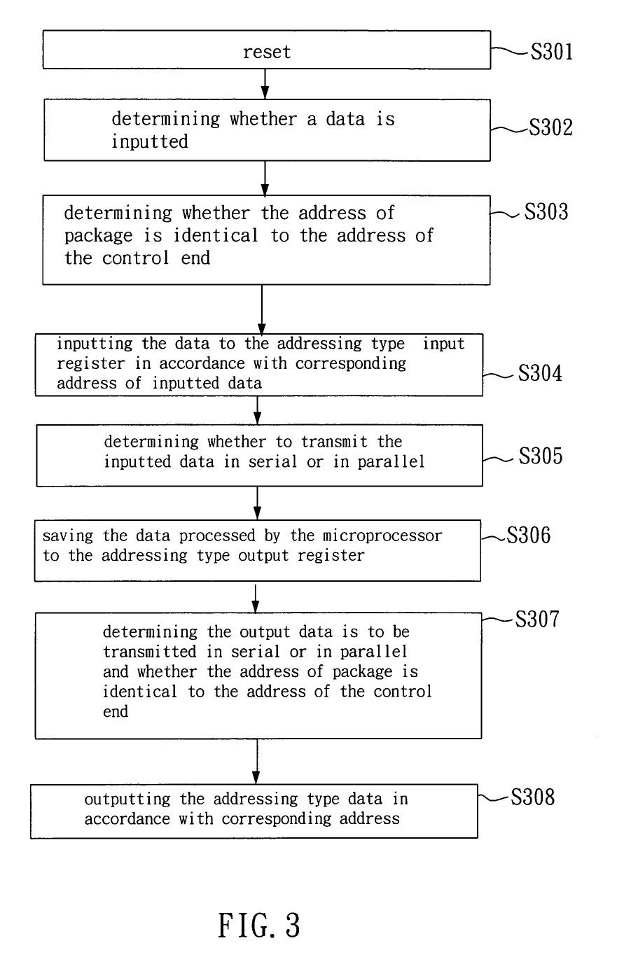

Please refer to FIG. 3 for the flow chart of the preferred embodiment of the present invention. In Step S301, firstly, it performs a reset on the addressing type input register 17 and addressing type output register 15. This is to confirm that there is no existing data in the registers. After resetting the system, it is further to determine whether there is data desired for input (Step S302). Should there be any data desired for input, the address in the package is further compared with the preset address of NWR pin 132 of the control end 13 to determine whether they are identical (Step S303). If the compared addresses are identical, then in Step S304, the data will be inputted, collocating with the NWR pin 132 by the bus 11.

In Step S305, the addressing type input register 17 will, in accordance with the inputted data, determine whether the input method to be either in serial or in parallel and then in accordance with the input method to transmit data to the microprocessor 14. Serial/parallel determining circuit 141 in microprocessor 14 will process the input data to determine whether to transmit desired output data in serial or in parallel. Then the data is saved in the addressing type output register 15 (Step S306). When the data is to be outputted, the addressing type output register 15 will process outputting, in accordance with the desired output data which is to be transmitted in serial or in parallel (Step S307). The addressing type output register 15 will further compare to determine whether the address in the package is identical to the preset address in NRD pin 133 of the control end 13. In Step S308, if the addresses are identical, the data will be outputted with NRD pin 133 via the bus 11. The corresponding input address of the NRW pin 132 and the output address of NRD pin 133 are different.

Although the present invention has been explained in relation to its preferred embodiment, it is to be understood that many other possible modifications and variations can be made without departing from the spirit and scope of the invention as hereinafter claimed.

1. An addressing type serial/parallel data transmitting system, comprising
a bus;
a data acquisition controller electrically connected to the bus, for receiving address and data from the bus;
an addressing type input register for saving inputting data;
a control end for controlling the input/output states of the addressing type serial/parallel data transmitting system;
a microprocessor for processing data transmitted from the data acquisition controller, wherein the microprocessor further comprises a serial/parallel determining circuit for determining whether to output data in serial or in parallel; and
an addressing type output register for saving desired outputting data processed by the microprocessor.

2. The system as claimed in claim 1, wherein the control end is an ALE pin.

3. The system as claimed in claim 1, wherein the control end is a NWR pin.

4. The system as claimed in claim 1, wherein the control end is a NRD pin.

5. The system as claimed in claim 2, wherein as the addressing type serial/parallel data transmitting system uses the ALE pin to control data transmission of the bus, the data of the bus is an address.

6. The system as claimed in claim 3, wherein as the addressing type serial/parallel data transmitting system uses the NWR pin to control data transmission of the bus, the data of the bus is inputted to the addressing type serial/parallel data transmitting system.

7. The system as claimed in claim 4, wherein as the addressing type serial/parallel data transmitting system uses the NRD pin to control data transmission of the bus, the data of the bus is outputted from the addressing type serial/parallel data transmitting system.

8. A data transmitting method for an addressing type serial/parallel data transmitting system, comprising the steps of:
(A) determining whether a data is inputted;
(B) inputting the data to the addressing type input register in accordance with corresponding address of inputted data;
(C) determining whether to transmit the inputted data in serial or in parallel, and transmitting the data to the microprocessor;
(D) saving the data processed by the microprocessor to the addressing type output register; and
(E) outputting the addressing type data in accordance with corresponding address of desired output data;
wherein the corresponding addresses in addressing type input register and addressing type output register are different.

9. The method as claimed in claim 8, wherein in step (A), the control end is utilized to determine whether or not the data is desired input data.

10. The method as claimed in claim 8, wherein in step (B), the control end collocates with the corresponding address of inputted data for data input.

11. The method as claimed in claim 8, wherein in step (D), the addressing type output register saves data processed by the microprocessor and desired for output and categorizes the data to serial and parallel transmitting data.

12. The method as claimed in claim 8, wherein in step (E), the control end collocates with the corresponding addresses of output data for operating the output of addressing type data.
